(19) United States
(12) Patent Application Publication
(10) Pub. No.: US 2014/0236512 A1
(43) Pub. Date: Aug. 21, 2014

(54) PLANAR STRUCTURE CHARACTERISTICS OBTAINED WITH LOOK UP TABLES

(71) Applicant: HEWLETT-PACKARD DEVELOPMENT COMPANY, L.P, (US)

(72) Inventor: John Yan, Fremont, CA (US)

(73) Assignee: HEWLETT-PACKARD DEVELOPMENT COMPANY, L.P., Houston, TX (US)

(21) Appl. No.: 13/770,456

(22) Filed: Feb. 19, 2013

(51) Int. Cl. G06F 17/00; G01R 27/02

(52) U.S. Cl. CPC G06F 17/00; G01R 27/02
USPC 702/65

(57) ABSTRACT

A system including a computing device to compare a first measured characteristic of a planar structure to a first look up table and obtain the relative permittivity of the planar structure based on the comparison of the first measured characteristic. The computing device compares a second measured characteristic of the planar structure to a second look up table to obtain the tangential loss of the planar structure based on the comparison of the second measured characteristic.

### BACKGROUND

Some electronic systems send and/or receive high frequency signals through various planar structures to perform their functions. These high frequency signals can be in the gigahertz (GHz) frequency range or higher. The planar structures have material characteristics that affect the electromagnetic propagation properties of the high speed signals propagating through the planar structures.

### BRIEF DESCRIPTION OF THE DRAWINGS

FIG. 1 is a diagram illustrating one example of a system that extracts the material properties of a fabricated planar structure in accordance with an example of the techniques of the present application.

FIG. 2 is a diagram illustrating one example of a planar structure that can have its material properties extracted by the system of FIG. 1 in accordance with an example of the techniques of the present application.

FIG. 3 is a diagram illustrating one example of a waveguide portion including a waveguide in accordance with an example of the techniques of the present application.

FIG. 4 is a diagram illustrating one example of a cross-section of a waveguide portion including a single stripline waveguide in accordance with an example of the techniques of the present application.

FIG. 5 is a diagram illustrating one example of a cross-section of a waveguide portion including a differential stripline waveguide in accordance with an example of the techniques of the present application.

FIG. 6 is a diagram illustrating one example of a cross-section of a waveguide portion including a coplanar waveguide in accordance with an example of the techniques of the present application.

FIG. 7 is a diagram illustrating one example of a cross-section of a waveguide portion including a differential coplanar waveguide in accordance with an example of the techniques of the present application.

FIG. 8A is a graph illustrating one example of a measured phase delay compared to a phase delay look up table over frequency in accordance with an example of the techniques of the present application.

FIG. 8B is a graph illustrating one example of the measured phase delay compared to the phase delay look up table in the nine to ten gigahertz range in accordance with an example of the techniques of the present application.

FIG. 9 is a graph illustrating one example of a measured insertion loss compared to a selected insertion loss look up table in accordance with an example of the techniques of the present application.

FIG. 10 is a flow chart diagram illustrating one example of the process of obtaining the relative permittivity and tangential loss of a planar structure in accordance with an example of the techniques of the present application.

### DETAILED DESCRIPTION

Planar structures include printed circuit board (PCB) structures, semiconductor structures, and packaging structures such as interposer structures. For example, in high quantity, low-cost PCB manufacturing, the PCB material and the PCB lamination process can vary from site-to-site and from batch-to-batch. Variations in the PCB material can include variations in resin chemistry, resin viscosity, and the quality of glass weave. Variations in the PCB lamination process can include variations in temperature, pressure, conductive trace etching chemistry, and humidity. These variations lead to differences in the electromagnetic propagation properties of high speed signals propagating through the PCBs. Differences in the electromagnetic propagation properties can translate into poor signal to noise ratios, an increase in bit error rates, an increase in bit loss per minute, an increase in packet loss, and unpredictable signal jitter. Monitoring the electromagnetic propagation properties of planar structures ensures higher quality system performance.

In one example, the present application provides techniques to quickly and accurately extract the material properties of fabricated planar structures based on quick electrical characterization tests and comparisons of each of the measured results to a look up table (LUT). In one example, a waveguide having a known geometry is fabricated on a planar structure and the waveguide is characterized using a measurement device, such as a vector network analyzer (VNA) or a time domain reflectometry (TDR) device or analyzer. The measured phase delay is compared to a phase delay LUT to obtain the relative permittivity ∈ᵣ or Er of the planar structure, also referred to as the Dk of the planar structure. An insertion loss LUT is selected based on the relative permittivity ∈ᵣ of the planar structure and the measured insertion loss is compared to the selected insertion loss LUT to obtain the tangential loss tan δ or tan d of the planar structure, also referred to as the amplitude loss, S21 loss, imaginary permittivity, and/or the Df of the planar structure. The relative permittivity ∈ᵣ and tangential loss tan δ of the planar structure indicate the electromagnetic propagation properties of the planar structure. The phase delay LUT and the insertion loss LUTs can be generated from simulated or previously measured results.

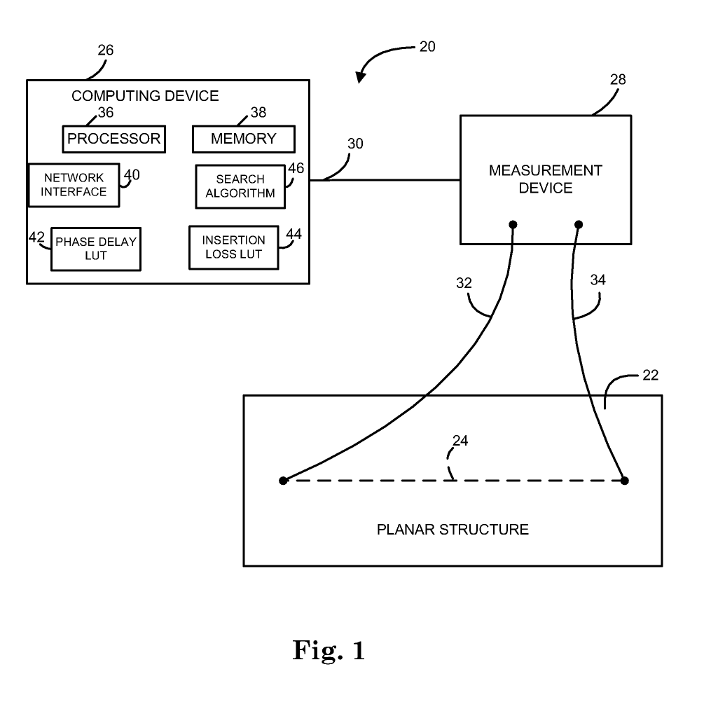

FIG. 1 is a diagram illustrating one example of a system 20 that extracts the material properties of a fabricated planar structure 22. In one example, planar structure 22 is a PCB panel that includes metallic traces to be populated with electronic components, such as resistors, capacitors, inductors, voltage regulators, and integrated circuits such as central processing units and random access memory. In one example, planar structure 22 is a semiconductor structure, such as an integrated circuit. In one example, planar structure 22 is a packaging structure, such as an interposer structure.

The planar structure 22 includes at least one waveguide 24. The waveguide 24 is embedded in planar structure 22 and manufactured to a known geometry. The waveguide 24 is configured to conduct high frequency signals. In one example, waveguide 24 is a metallic waveguide. In one example, waveguide 24 is configured to conduct high frequency signals of greater than 1 GHz. In one example, waveguide 24 is a single stripline. In one example, waveguide 24 is a differential stripline. In one example, waveguide 24 is a coplanar waveguide (CPW). In one example, waveguide 24 is a differential CPW. In other examples, waveguide 24 can be another suitable waveguide.

The system 20 includes a computing device 26 and a measurement device 28. The computing device 26 is communicatively coupled to measurement device 28 by communications path 30. The measurement device 28 is communicatively coupled to waveguide 24 by a first communications path 32 and a second communications path 34.

In one example, computing device 26 includes a processor 36, memory 38, also referred to as machine-readable (or computer-readable) storage media 38, and a network interface 40. The processor 36 is connected to network interface 40 to communicate over a network and the processor 36 is connected to memory 38. The processor 30 can include a microprocessor, a microcontroller, a processor module or subsystem, a programmable integrated circuit, a programmable gate array, and/or another control/computing device. The memory 38 can include different forms of memory including semiconductor memory devices, such as dynamic or static random access memories (DRAMs or SRAMs), erasable and programmable read-only memories (EPROMs), electrically erasable and programmable read-only memories (EEPROMs), and flash memories; magnetic disks such as fixed, floppy, and removable disks; other magnetic media including magnetic tape; optical media such as compact disks (CDs) and digital video disks (DVDs); and other types of storage devices. The techniques of the present application can be implemented on system 20 having machine-readable instructions stored in memory 38 and executed on processor 36. The machine-readable instructions can be provided on one computer-readable or machine-readable storage medium 38, or alternatively, can be provided on multiple computer-readable or machine-readable storage media 38 distributed in system 20 at multiple nodes. Such computer-readable or machine-readable storage media 38 is considered to be part of an article or article of manufacture, which can refer to any manufactured single component or multiple components. In one example, memory is located at a remote site from which machine-readable instructions can be downloaded over a network via network interface 40 for execution by processor 30.

The measurement device 28 measures the phase delay per unit length of waveguide 24 and the insertion loss per unit length of waveguide 24. The measurement device 28 provides the measured phase delay and insertion loss of waveguide 24 to computing device 26 via communications path 30. In one example, measurement device 28 simultaneously measures the phase delay per unit length of waveguide 24 and the insertion loss per unit length of waveguide 24.

In one example, measurement device 28 is a VNA that sweeps a narrow frequency band across a broad range of frequencies to provide broadband measurements of the phase delay and insertion loss of waveguide 24. Sweeping a narrow frequency band across a broad range of frequencies suppresses noise that is out of the narrow frequency band, such that the VNA can provide a dynamic range on the order of 130 decibels (dB).

In one example, measurement device 28 is a TDR device that provides time domain broadband measurements of the phase delay and insertion loss of waveguide 24. Next, Fourier transforms or fast Fourier transforms (FFTs) are used to provide the phase delay and insertion loss of waveguide 24 over frequency. The TDR device is a broadband device that can provide a dynamic range on the order of 40 dB to 80 dB.

The computing device 26 receives the measured phase delay and insertion loss of waveguide 24. The computing device 26 compares the measured phase delay to a phase delay LUT 42 to obtain the relative permittivity ∈ᵣ of planar structure 22. Next, computing device 26 selects an insertion loss LUT 44 corresponding to the relative permittivity ∈ᵣ of planar structure 22. The computing device 26 compares the measured insertion loss to the selected insertion loss LUT 44 to obtain the tangential loss tan δ of planar structure 22. Using the relative permittivity ∈ᵣ and tangential loss tan δ of planar structure 22, the quality of planar structure 22 can be determined and planar structure 22 can be passed or rejected.

In one example, computing device 26 uses a search algorithm 46 to compare the measured phase delay to phase delay LUT 42 and/or to compare the measured insertion loss to an insertion loss LUT 44. In one example, computing device 26 uses a recursive search algorithm to compare the measured phase delay to phase delay LUT 42 and/or to compare the measured insertion loss to an insertion loss LUT 44. In one example, computing device 26 uses a sequential search algorithm to compare the measured phase delay to phase delay LUT 42 and/or to compare the measured insertion loss to an insertion loss LUT 44. In one example, computing device 26 uses a hash search algorithm to compare the measured phase delay to phase delay LUT 42 and/or to compare the measured insertion loss to an insertion loss LUT 44. In one example, computing device 26 uses a binary search algorithm to compare the measured phase delay to phase delay LUT 42 and/or to compare the measured insertion loss to an insertion loss LUT 44.

In one example, computing device 26 interpolates between points in phase delay LUT 42 to obtain an interpolated value of the relative permittivity ∈ᵣ. This interpolated value is used as the relative permittivity ∈ᵣ for indicating the quality of planar structure 22. The interpolated value of the relative permittivity ∈ᵣ is indexed to an indexed relative permittivity ∈ᵣ value that has a corresponding insertion loss LUT 44. The insertion loss LUT 44 that corresponds to the indexed relative permittivity ∈ᵣ is selected to obtain the tangential loss tan δ of planar structure 22.

In one example, computing device 26 interpolates between points in the selected insertion loss LUT 44 to obtain an interpolated value of the tangential loss tan δ of planar structure 22. The interpolated value of the tangential loss tan δ is used for indicating the quality of planar structure 22.

Each phase delay LUT 44 and insertion loss LUT 44 is generated for waveguide 24, which has a known geometry. In one example, phase delay LUT 42 is generated using a three dimensional (3D) field solver. In one example, phase delay LUT 42 is generated using controlled experiments consisting of known material properties. In one example, phase delay LUT 42 is generated using resonant cavity structures, one resonant cavity for each of many narrow frequency bands. In one example, insertion loss LUT 44 is generated using a three dimensional (3D) field solver. In one example, insertion loss LUT 44 is generated using controlled experiments consisting of known material properties. In one example, insertion loss LUT 44 is generated using resonant cavity structures, one resonant cavity for each of many narrow frequency bands.

The present application provides techniques to accurately extract the material properties of fabricated planar structures very quickly, such as within seconds, based on simple to use electrical characterization tests and computationally inexpensive comparisons of each of the measured results to a LUT. The extracted material properties can be used to indicate the quality of the planar structure and/or for simulations and designing other planar structures.

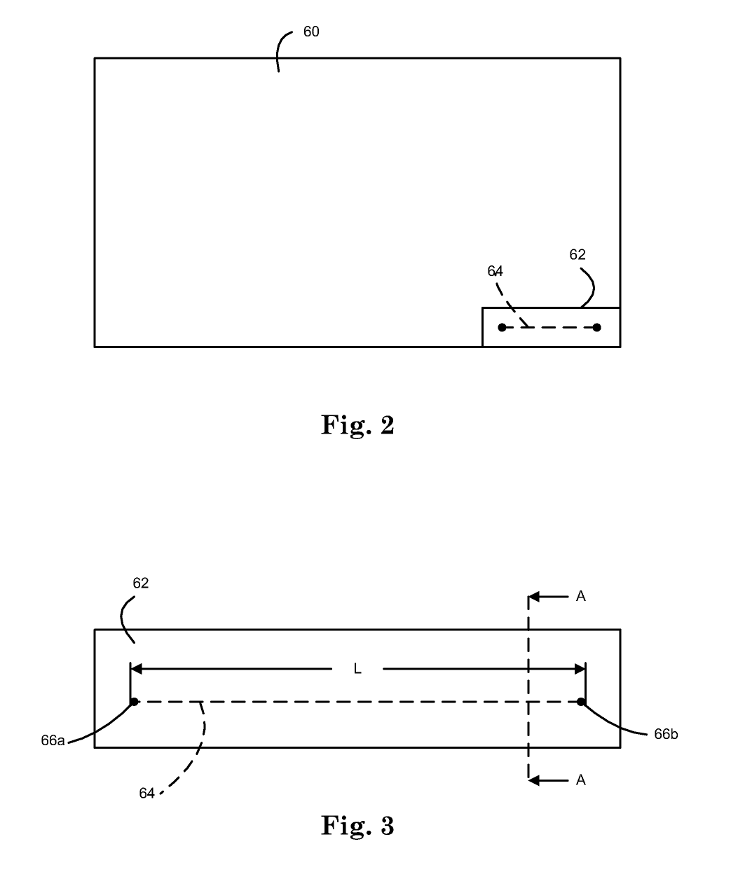

FIG. 2 is a diagram illustrating one example of a planar structure 60 that can have its material properties extracted by system 20 (shown in FIG. 1). The planar structure 60 is illustrated as having a rectangular shape. However, planar structure 60 can be any suitable shape, such as a square shape, a rectangular shape, a circular shape, an oblong shape, or any combination of the above. The planar structure 60 is similar to planar structure 22 (shown in FIG. 1). In one example, planar structure 60 is a PCB panel that includes metallic traces to be populated with electronic components, such as resistors, capacitors, inductors, voltage regulators, and integrated circuits such as central processing units and random access memory. In one example, planar structure 60 is a semiconductor structure, such as an integrated circuit. In one example, planar structure 60 is a packaging structure, such as an interposer structure.

The planar structure 60 includes waveguide portion 62, which includes a waveguide 64. In one example, planar structure 60 includes a homogeneous medium and waveguide 64 is embedded in or encased by the homogeneous medium. In one example, planar structure 60 and waveguide 64 are configured to conduct a homogeneous electromagnetic wave. In one example, planar structure 60 and waveguide 64 are configured to conduct a transverse electromagnetic (TEM) wave.

The waveguide 64 is embedded in planar structure 60 and manufactured to a known geometry. The waveguide 64 is configured to conduct high frequency signals. The waveguide 64 is similar to waveguide 24 (shown in FIG. 1). In one example, waveguide 64 is configured to conduct high frequency signals of greater than 1 GHz. In one example, waveguide 64 can be a single stripline. In one example, waveguide 64 can be a differential stripline. In one example, waveguide 64 can be a coplanar waveguide (CPW). In one example, waveguide 64 can be a differential CPW. In other examples, waveguide 64 can be another suitable waveguide.

In one example, waveguide portion 62 of planar structure 60 is a breakout tab, where waveguide portion 62 is broken away from planar structure 60 and characteristics of waveguide 64 are measured by a measurement device, such as measurement device 28 (shown in FIG. 1). These measured characteristics of waveguide 64 are provided to a computing device, such as computing device 26 (shown in FIG. 1), which compares the measured characteristics to LUTs as described in the description of system 20 to determine the relative permittivity ∈ᵣ and tangential loss tan δ of planar structure 60. Breaking waveguide portion 62 away from planar structure 60 can simplify handling and make it easier to measure the characteristics of waveguide 64 to determine the relative permittivity ∈ᵣ and tangential loss tan δ of planar structure 60.

In one example, waveguide portion 62 is not a breakout tab and characteristics of waveguide 64 are measured with waveguide 64 as part of planar structure 60 by a measurement device, such as measurement device 28 (shown in FIG. 1). The measured characteristics of waveguide 64 are provided to a computing device, such as computing device 26 (shown in FIG. 1) and compared to LUTs as described in the description of system 20 to determine the relative permittivity ∈ᵣ and tangential loss tan δ of planar structure 60. In other examples, waveguide 64 can be embedded at any suitable location in planar structure 60.

FIG. 3 is a diagram illustrating one example of waveguide portion 62 including waveguide 64 and probe pads 66a and 66b. Each end of waveguide 64 is electrically coupled to one of the probe pads 66a and 66b.

In operation, a measurement device, such as measurement device 28 (shown in FIG. 1), is electrically coupled to probe pads 66a and 66b. The measurement device measures the characteristics of waveguide 64 and provides the measured characteristics to a computing device, such as computing device 26 (shown in FIG. 1). The computing device compares the measured characteristics to LUTs as described in the description of system 20 to determine the relative permittivity ∈ᵣ and tangential loss tan δ of planar structure 60.

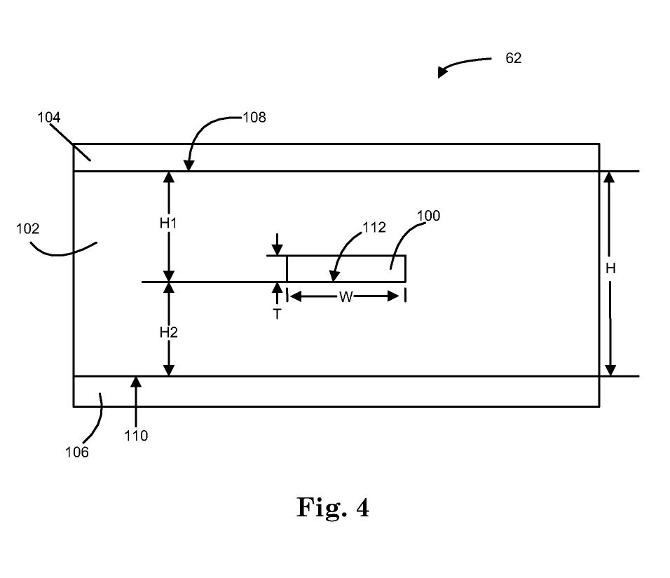

FIG. 4 is a diagram illustrating one example of a cross-section of waveguide portion 62 including a single stripline waveguide 100. The cross-section of waveguide portion 62 is taken along the line A-A in FIG. 3.

The waveguide portion 62 includes stripline 100, structural material 102, a top reference plane 104, and a bottom reference plane 106. The stripline 100 is embedded or encased in structural material 102. The top reference plane 104 is situated on top surface 108 of structural material 102. The bottom reference plane 106 is situated on bottom surface 110 of structural material 102. In one example, stripline 100 is a metallic stripline trace. In one example, top reference plane 104 is a conductive reference plane. In one example, top reference plane 104 is a metallic reference plane. In one example, bottom reference plane 106 is a conductive reference plane. In one example, bottom reference plane 106 is a metallic reference plane. In other examples, planar structure 60 and waveguide portion 62 do not include top reference plane 104 and bottom reference plane 106. In other examples, planar structure 60, including waveguide portion 62, includes many layers of structural material and/or reference planes.

The waveguide portion 62 has the same cross-section as planar structure 60 such that the relative permittivity ∈ᵣ and tangential loss tan δ of structural material 102 in waveguide portion 62 is the same as the relative permittivity ∈ᵣ and tangential loss tan δ of planar structure 60. In one example, structural material 102 is a homogeneous material. In one example, structural material 102 is a dielectric material. In one example of a PCB, structural material 102 is a homogeneous material including a core dielectric material, glass-weave material, and prepreg material, where the structural material 102 is considered to be homogeneous for TEM waves in the case of a waveguide because the spatial variations in the material are electrically smaller than the wavelength of the propagating TEM waves.

The stripline 100 has a geometry that corresponds to the geometry of a stripline that was measured to generate the phase delay LUTs, such as phase delay LUT 42 (shown in FIG. 1), and the insertion loss LUTs, such as insertion loss LUT 44 (shown in FIG. 1). The stripline 100 has a thickness T, width W, and length L (shown in FIG. 3). In other examples, stripline 100 can be any suitable shape and size.

The stripline 100 is situated a predetermined distance away from adjacent structures and peripheral components to ensure that the adjacent structures and peripheral components do not interfere with the electromagnetic waves conducted by stripline 100 and propagating through structural material 102. This distance is based on the height H of structural material 102 from top surface 108 to bottom surface 110. To avoid interference from adjacent structures and peripheral components, stripline 100 is situated at least about five times the height H away from the adjacent structures and peripheral components. This ensures that the adjacent components and peripheral components do not interfere with the electromagnetic waves, such as TEM waves, conducted by stripline 100 and propagating through structural material 102.

The stripline 100 has a bottom surface 112 that is situated a distance H1 from top surface 108 and a distance H2 from bottom surface 110. The height H is equal to the distance H1 plus the distance H2. In one example, stripline 100 is a symmetric stripline, where the distance H1 is about equal to the distance H2 to center stripline 100 in structural material 102. In one example, stripline 100 is an asymmetric stripline, where the distance H1 is about ⅓ of the height H and the distance H2 is about ⅔ of the height H. In one example, stripline 100 is an asymmetric stripline, where the distance H1 is about ⅔ of the height H and the distance H2 is about ⅓ of the height H. In one example, stripline 100 is an asymmetric stripline, where the distance H1 is different than the distance H2.

In one example of a PCB, structural material 102 is a homogeneous material including a core dielectric material, glass-weave material, and prepreg material, where the core dielectric material is situated between the bottom surface 112 of stripline 100 and the bottom surface 110, and the glass-weave material is situated between the bottom surface 112 of stripline 100 and top surface 108.

In operation, a measurement device, such as measurement device 28, is electrically coupled to stripline 100 at probes, such as probes 66a and 66b. The measurement device measures the phase delay per unit length of stripline 100 and the insertion loss per unit length of stripline 100. The measurement device provides the measured phase delay and insertion loss of stripline 100 to a computing device, such as computing device 26. In one example, top reference plane 104 and bottom reference plane 106 are electrically coupled to a reference, such as ground, while taking the measurements. In one example, top reference plane 104 and bottom reference plane 106 are electrically coupled to a different reference voltage, other than ground, while taking the measurements. In one example, the measurement device simultaneously measures the phase delay per unit length of stripline 100 and the insertion loss per unit length of stripline 100.

The computing device receives the measured phase delay and insertion loss of stripline 100 and compares the measured phase delay to a phase delay LUT, such as phase delay LUT 42, to obtain the relative permittivity ∈ᵣ of planar structure 60. Next, the computing device selects an insertion loss LUT, such as insertion loss LUT 44, corresponding to the relative permittivity ∈ᵣ of planar structure 60. The computing device compares the measured insertion loss to the selected insertion loss LUT to obtain the tangential loss tan δ of planar structure 60. Using the relative permittivity ∈ᵣ and tangential loss tan δ of planar structure 60, the quality of planar structure 60 can be determined and planar structure 60 can be passed or rejected.

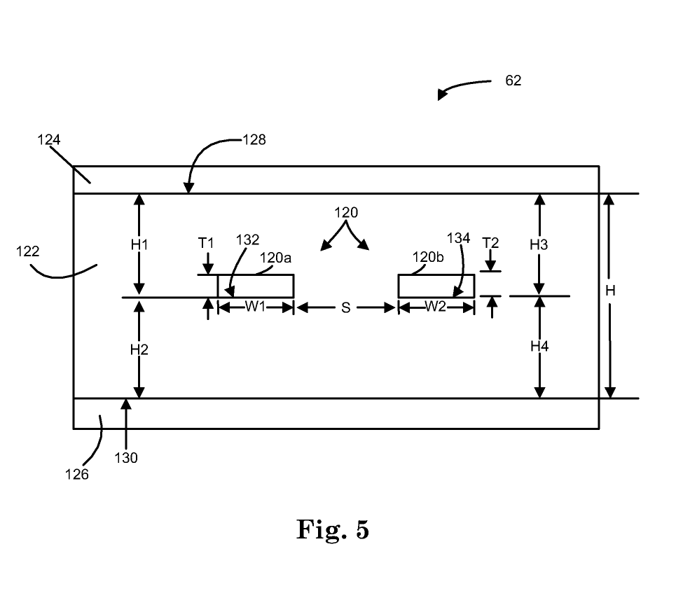

FIG. 5 is a diagram illustrating one example of a cross-section of waveguide portion 62 including a differential stripline waveguide 120, which includes a first stripline 120a and a second stripline 120b. The cross-section of waveguide portion 62 is taken along the line A-A in FIG. 3.

The waveguide portion 62 includes differential stripline 120, structural material 122, a top reference plane 124, and a bottom reference plane 126. The differential stripline 120, including first stripline 120a and second stripline 120b, is embedded or encased in structural material 122. The top reference plane 124 is situated on top surface 128 of structural material 122. The bottom reference plane 126 is situated on bottom surface 130 of structural material 122. In one example, each of first stripline 120a and second stripline 120b is a metallic stripline trace. In one example, top reference plane 124 is a conductive reference plane. In one example, top reference plane 124 is a metallic reference plane. In one example, bottom reference plane 126 is a conductive reference plane. In one example, bottom reference plane 126 is a metallic reference plane. In other examples, planar structure 60 and waveguide portion 62 do not include top reference plane 124 and bottom reference plane 126. In other examples, planar structure 60, including waveguide portion 62, includes many layers of structural material and/or reference planes.

The waveguide portion 62 has the same cross-section as planar structure 60 such that the relative permittivity ∈ᵣ and tangential loss tan δ of structural material 122 in waveguide portion 62 is the same as the relative permittivity ∈ᵣ and tangential loss tan δ of planar structure 60. In one example, structural material 122 is a homogeneous material. In one example, structural material 122 is a dielectric material. In one example of a PCB, structural material 122 is a homogeneous material including a core dielectric material, glass-weave material, and prepreg material, where the structural material 122 is considered to be homogeneous for TEM waves in the case of a waveguide because the spatial variations in the material are electrically smaller than the wavelength of the propagating TEM waves.

Each of first stripline 120a and second stripline 120b has a geometry that corresponds to the geometry of a differential stripline that was measured to generate the phase delay LUTs, such as phase delay LUT 42 (shown in FIG. 1), and the insertion loss LUTs, such as insertion loss LUT 44 (shown in FIG. 1). The first stripline 120a of differential stripline 120 has a thickness T1, width W1, and length L (shown in FIG. 3). The second stripline 120b of differential stripline 120 has a thickness T2, width W2, and length L (shown in FIG. 3). In one example, the thickness T1 is substantially the same as the thickness T2. In one example, the width W1 is substantially the same as the width W2. In one example, the thickness T1 is different than the thickness T2. In one example, the width W1 is different than the width W2. In other examples, first stripline 120a and second stripline 120b can be any suitable shape and size.

Each of first stripline 120a and second stripline 120b is situated a distance away from adjacent structures and peripheral components to ensure that the adjacent structures and peripheral components do not interfere with the electromagnetic waves conducted by stripline 120 and propagating through structural material 122. This distance is based on the height H of structural material 122 from top surface 128 to bottom surface 130. To avoid interference from adjacent structures and peripheral components, each of first stripline 120a and second stripline 120b is situated a distance of about five times the height H away from the adjacent structures and peripheral components. This ensures that the adjacent structures and peripheral components do not interfere with the electromagnetic waves, such as the TEM waves, conducted by each of first stripline 120a and second stripline 120b and propagating through structural material 122.

Electromagnetic waves propagating through first stripline 120a interact with second stripline 120b and electromagnetic waves propagating through second stripline 120b interact with first stripline 120a. The first stripline 120a and second stripline 120b are spaced apart a distance S to control the differential and common mode impedance of the differential stripline 120. In one example, the distance S is 9 mils, W1 is 7 mils, W2 is 7 mils, T1 is 1.2 mils, T2 is 1.2 mils, and H is 11.5 mils, where 1 mil is equal to 0.001 inches, which is equal to 25.4 micrometers (um).

The first stripline 120a has a bottom surface 132 and second stripline 120b has a bottom surface 134. The bottom surface 132 is situated a distance H1 from top surface 128 and a distance H2 from bottom surface 130. The bottom surface 134 is situated a distance H3 from top surface 128 and a distance H4 from bottom surface 130. The height H is equal to the distance H1 plus the distance H2. Also, the height H is equal to the distance H3 plus the distance H4. In one example, differential stripline 120 is an edge coupled differential stripline, where the distance H1 is equal to the distance H3, and the distance H2 is equal to the distance H4. In one example, differential stripline 120 is a symmetric edge coupled differential stripline, where the distance H1 is equal to the distance H3, the distance H2 is equal to the distance H4, and the distances H1 and H3 are about equal to the distances H2 and H4 to center first stripline 120a and second stripline 120b in structural material 122. In one example, differential stripline 120 is an asymmetric edge coupled differential stripline, where the distance H1 is equal to the distance H3, the distance H2 is equal to the distance H4, and the distances H1 and H3 are not about equal to the distances H2 and H4. In one example, the distance H1 is less than the distance H2 and the distance H3 is greater than the distance H4 to situate first stripline 120a in the upper left quadrant and second stripline 120b in the lower right quadrant. In other examples, first stripline 120a and second stripline 120b are situated in other, different quadrants. In another example of a differential stripline, the differential stripline is a broad coupled differential stripline, where one stripline trace is situated above the other stripline trace such that the stripline traces couple across their widths. In other examples of a waveguide in waveguide portion 62, the waveguide includes four or more stripline traces in different arrangements and/or quadrants.

In one example of a PCB, structural material 122 is a homogeneous material including a core dielectric material, glass-weave material, and prepreg material, where the core dielectric material is situated between the bottom surfaces 132 and 134 and bottom surface 130, and the glass-weave material is situated between the bottom surfaces 132 and 134 and top surface 128.

In operation, a measurement device, such as measurement device 28, is electrically coupled to each end of first stripline 120a and to each end of second stripline 120b. The measurement device transmits and receives a differential signal through the first and second striplines 120a and 120b to measure the phase delay per unit length of differential stripline 120 and the differential insertion loss, sometimes referred to as Sdd21, per unit length of differential stripline 120. The differential stripline 120 can be employed to reject common mode noise, sometimes referred to as simultaneously switching output noise, and to improve or boost the signal by about 3 dB. The measurement device provides the measured phase delay and insertion loss of differential stripline 120 to a computing device, such as computing device 26. In one example, top reference plane 124 and bottom reference plane 126 are electrically coupled to a reference, such as ground, while taking the measurements. In one example, top reference plane 124 and bottom reference plane 126 are electrically coupled to a different reference voltage, other than ground, while taking the measurements. In one example, the measurement device simultaneously measures the phase delay per unit length of differential stripline 120 and the differential insertion loss per unit length of differential stripline 120.

In one example, the measurement device is a VNA that sweeps a narrow frequency band across a broad range of frequencies to provide broadband measurements of the phase delay and differential insertion loss of differential stripline 120. Sweeping a narrow frequency band across a broad range of frequencies suppresses noise that is out of the narrow frequency band, such that the VNA can provide a dynamic range on the order of 130 dB. In one example, the VNA provides a 1 milliwatt (mW) signal having a 0 degree phase angle to first stripline 120a and a 1 mW signal having a 180 degree phase angle to second stripline 120b. In one example, the VNA provides a 5 decibel milliwatt (dBmW) signal having a 0 degree phase angle to first stripline 120a and a 5 dBmW signal having a 180 degree phase angle to second stripline 120b.

In one example, the measurement device is a TDR device that provides time domain broadband measurements of the phase delay and insertion loss of differential stripline 120. Next, Fourier transforms or fast Fourier transforms (FFTs) are used to provide the phase delay and insertion loss of differential stripline 120 over frequency. The TDR device is a broadband device that can provide a dynamic range on the order of 40 dB to 80 dB. In one example, the TDR device provides a +1 volt signal to first stripline 120a and a −1 volt signal to second stripline 120b.

The computing device receives the measured phase delay and differential insertion loss of differential stripline 120 and compares the measured phase delay to a phase delay LUT, such as phase delay LUT 42, to obtain the relative permittivity ∈ᵣ of planar structure 60. Next, the computing device selects an insertion loss LUT, such as insertion loss LUT 44, corresponding to the relative permittivity ∈ᵣ of planar structure 60. The computing device compares the measured insertion loss to the selected insertion loss LUT to obtain the tangential loss tan δ of planar structure 60. Using the relative permittivity ∈ᵣ and tangential loss tan δ of planar structure 60, the quality of planar structure 60 can be determined and planar structure 60 can be passed or rejected.

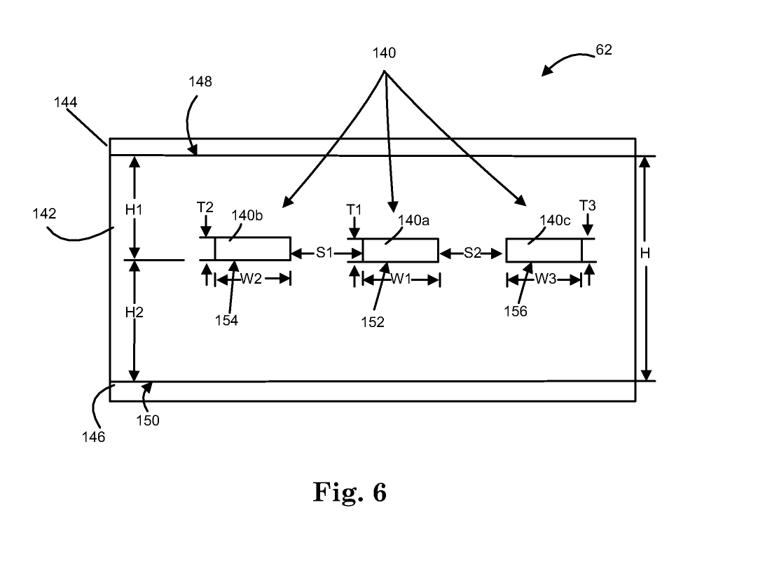

FIG. 6 is a diagram illustrating one example of a cross-section of waveguide portion 62 including a coplanar waveguide (CPW) 140, which includes a signal line 140a, a first reference line 140b, and a second reference line 140c. The cross-section of waveguide portion 62 is taken along the line A-A in FIG. 3.

The waveguide portion 62 includes CPW 140, structural material 142, a top reference plane 144, and a bottom reference plane 146. The CPW 140, including signal line 140a, first reference line 140b, and second reference line 140c, is embedded or encased in structural material 142. In one example, signal line 140a is a metallic signal line trace. In one example, first reference line 140b is a conductive reference line. In one example, first reference line 140b is a metallic reference line. In one example, second reference line 140c is a conductive reference line. In one example, second reference line 140c is a metallic reference line.

The top reference plane 144 is situated on top surface 148 of structural material 142. The bottom reference plane 146 is situated on bottom surface 150 of structural material 142. In one example, top reference plane 144 is a conductive reference plane. In one example, top reference plane 144 is a metallic reference plane. In one example, bottom reference plane 146 is a conductive reference plane. In one example, bottom reference plane 146 is a metallic reference plane. In other examples, planar structure 60 and waveguide portion 62 do not include top reference plane 144 and bottom reference plane 146. In other examples, planar structure 60, including waveguide portion 62, includes many layers of structural material and/or reference planes.

The waveguide portion 62 has the same cross-section as planar structure 60 such that the relative permittivity ∈ᵣ and tangential loss tan δ of structural material 142 in waveguide portion 62 is the same as the relative permittivity ∈ᵣ and tangential loss tan δ of planar structure 60. In one example, structural material 142 is a homogeneous material. In one example, structural material 142 is a dielectric material. In one example of a PCB, structural material 142 is a homogeneous material including a core dielectric material, glass-weave material, and prepreg material, where the structural material 142 is considered to be homogeneous for TEM waves in the case of a waveguide because the spatial variations in the material are electrically smaller than the wavelength of the propagating TEM waves.

The CPW 140 has a geometry that corresponds to the geometry of a CPW that was measured to generate the phase delay LUTs, such as phase delay LUT 42 (shown in FIG. 1), and the insertion loss LUTs, such as insertion loss LUT 44 (shown in FIG. 1). The signal line 140a has a thickness T1, width W1, and length L (shown in FIG. 3). The first reference line 140b has a thickness T2, width W2, and length L (shown in FIG. 3). The second reference line 140c has a thickness T3, width W3, and length L (shown in FIG. 3). In one example, the thicknesses T1, T2, and T3 are substantially the same thickness. In one example, the widths W1, W2, and W3 are substantially the same widths. In one example, the thickness T1 is different than the thicknesses T2 and T3 and the thicknesses T2 and T3 are substantially the same thickness. In one example, the width W1 is different than the widths W2 and W3 and the widths W2 and W3 are substantially the same widths. In one example, each of the thicknesses T1, T2, and T3 are different. In one example, each of the widths W1, W2, and W3 are different. In other examples, signal line 140a, first reference line 140b, and second reference line 140c can be any suitable shape and size.

The signal line 140a and first reference line 140b are spaced apart a distance S1 and the signal line 140a and second reference line 140c are spaced apart a distance S2. The first and second reference lines 140b and 140c provide additional isolation and a reference, such as ground, to ensure that adjacent structures and peripheral components do not interfere with the electromagnetic wave conducted by signal line 140a and propagating through structural material 142. In one example, the distance S1 is substantially the same as the distance S2. In one example, the distance S1 is different than the distance S2.

The signal line 140a has a bottom surface 152, first reference line 140b has a bottom surface 154, and second reference line 140c has a bottom surface 156, which are coplanar and situated a distance H1 from top surface 148 and a distance H2 from bottom surface 150. The height H is equal to the distance H1 plus the distance H2. In one example, CPW 140 is a symmetric CPW, where the distance H1 is about equal to the distance H2 to center signal line 140a, first reference line 140b, and second reference line 140c in structural material 142. In one example, CPW 140 is an asymmetric CPW, where the distance H1 is about ⅓ of the height H and the distance H2 is about ⅔ of the height H. In one example, CPW 140 is an asymmetric CPW, where the distance H1 is about ⅔ of the height H and the distance H2 is about ⅓ of the height H. In one example, CPW 140 is an asymmetric CPW, where the distance H1 is different than the distance H2.

In one example of a PCB, structural material 142 is a homogeneous material including a core dielectric material, glass-weave material, and prepreg material, where the core dielectric material is situated between the bottom surfaces 152, 154, and 156 and bottom surface 150, and the glass-weave material is situated between the bottom surfaces 152, 154, and 156 and top surface 148.

In operation, a measurement device, such as measurement device 28, is electrically coupled to each end of signal line 140a, and first reference line 140b and second reference line 140c are electrically coupled to a reference, such as ground. In one example, first reference line 140b and second reference line 140c are electrically coupled to ground, which puts CPW 140 in a ground-signal-ground (GSG) configuration to provide additional noise immunity, including common mode noise immunity. The CPW 140 in the GSG configuration can be used as a signal feed to an antenna for wireless applications, such as mobile wireless applications, where first reference line 140b and second reference line 140c provide additional shielding.

The measurement device transmits and receives a signal through signal line 140a to measure the phase delay per unit length of CPW 140 and the insertion loss per unit length of CPW 140. The measurement device provides the measured phase delay and insertion loss of CPW 140 to a computing device, such as computing device 26. In one example, first reference line 140b and second reference line 140c are electrically coupled to a reference, such as ground, while taking the measurements. In one example, top reference plane 144 and bottom reference plane 146 are electrically coupled to a reference, such as ground, while taking the measurements. In one example, top reference plane 144 and bottom reference plane 146 are electrically coupled to a different reference voltage, other than ground, while taking the measurements. In one example, the measurement device simultaneously measures the phase delay per unit length of CPW 140 and the insertion loss per unit length of CPW 140.

The computing device receives the measured phase delay and insertion loss of CPW 140 and compares the measured phase delay to a phase delay LUT, such as phase delay LUT 42, to obtain the relative permittivity ∈ᵣ of planar structure 60. Next, the computing device selects an insertion loss LUT, such as insertion loss LUT 44, corresponding to the relative permittivity ∈ᵣ of planar structure 60. The computing device compares the measured insertion loss to the selected insertion loss LUT to obtain the tangential loss tan δ of planar structure 60. Using the relative permittivity ∈ᵣ and tangential loss tan δ of planar structure 60, the material quality of planar structure 60 can be determined.

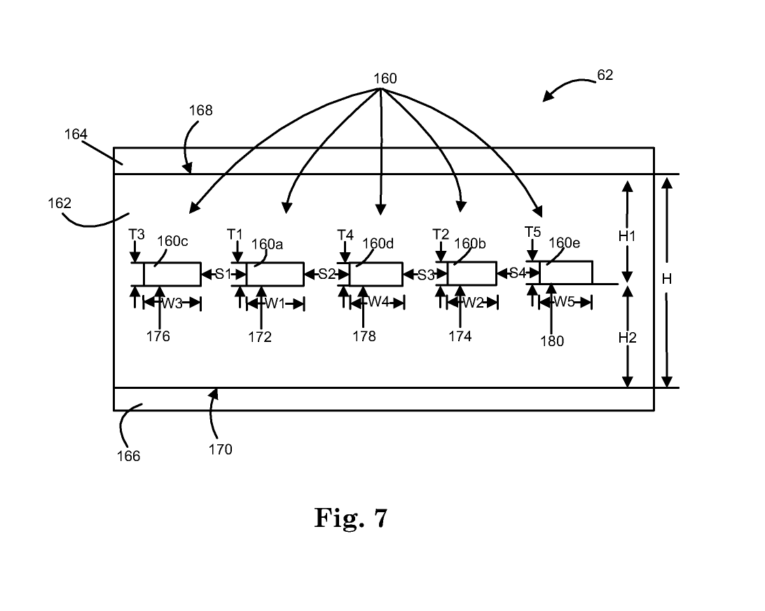

FIG. 7 is a diagram illustrating one example of a cross-section of waveguide portion 62 including a differential coplanar waveguide (DCPW) 160, which includes a first signal line 160a, a second signal line 160b, a first reference line 160c, a second reference line 160d, and a third reference line 160e. The cross-section of waveguide portion 62 is taken along the line A-A in FIG. 3.

The waveguide portion 62 includes DCPW 160, structural material 162, a top reference plane 164, and a bottom reference plane 166. The DCPW 160, including first signal line 160a, second signal line 160b, first reference line 160c, second reference line 160d, and third reference line 160e, is embedded or encased in structural material 162. In one example, signal line 160a and signal line 160b are each metallic signal line traces. In one example, first reference line 160c is a conductive reference line. In one example, first reference line 160c is a metallic reference line. In one example, second reference line 160d is a conductive reference line. In one example, second reference line 160d is a metallic reference line. In one example, third reference line 160e is a conductive reference line. In one example, third reference line 160e is a metallic reference line.

The top reference plane 164 is situated on top surface 168 of structural material 162. The bottom reference plane 166 is situated on bottom surface 170 of structural material 162. In one example, top reference plane 164 is a conductive reference plane. In one example, top reference plane 164 is a metallic reference plane. In one example, bottom reference plane 166 is a conductive reference plane. In one example, bottom reference plane 166 is a metallic reference plane. In other examples, planar structure 60 and waveguide portion 62 do not include top reference plane 164 and bottom reference plane 166. In other examples, planar structure 60, including waveguide portion 62, includes many layers of structural material and/or reference planes.

The waveguide portion 62 has the same cross-section as planar structure 60 such that the relative permittivity ∈ᵣ and tangential loss tan δ of structural material 162 in waveguide portion 62 is the same as the relative permittivity ∈ᵣ and tangential loss tan δ of planar structure 60. In one example, structural material 162 is a homogeneous material. In one example, structural material 162 is a dielectric material. In one example of a PCB, structural material 162 is a homogeneous material including a core dielectric material, glass-weave material, and prepreg material, where structural material 162 is considered to be homogeneous for TEM waves in the case of a waveguide because the spatial variations in the material are electrically smaller than the wavelength of the propagating TEM waves.

The DCPW 160 has a geometry that corresponds to the geometry of a DCPW that was measured to generate the phase delay LUTs, such as phase delay LUT 42 (shown in FIG. 1), and the insertion loss LUTs, such as insertion loss LUT 44 (shown in FIG. 1). The first signal line 160a has a thickness T1, width W1, and length L (shown in FIG. 3). The second signal line 160b has a thickness T2, width W2, and length L (shown in FIG. 3). The first reference line 160c has a thickness T3, width W3, and length L (shown in FIG. 3). The second reference line 160d has a thickness T4, width W4, and length L (shown in FIG. 3). The third reference line 160e has a thickness T5, width W5, and length L (shown in FIG. 3). In one example, the thicknesses T1, T2, T3, T4, and T5 are substantially the same thickness. In one example, the widths W1, W2, W3, W4, and W5 are substantially the same widths. In one example, the thicknesses T1 and T2 are substantially the same and different than the thicknesses T3, T4, and T5 and the thicknesses T3, T4, and T5 are substantially the same thickness. In one example, the widths W1 and W2 are substantially the same and different than the widths W3, W4, and W5 and the widths W3, W4, and W5 are substantially the same widths. In one example, each of the thicknesses T1, T2, T3, T4, and T5 can be different. In one example, each of the widths W1, W2, W3, W4, and W5 can be different. In other examples, first signal line 160a, second signal line 160b, first reference line 160c, second reference line 160d, and third reference line 160e can be any suitable shape and size.

The first signal line 160a and first reference line 160c are spaced apart a distance S1, the first signal line 160a and second reference line 160d are spaced apart a distance S2, the second signal line 160b and second reference line 160d are spaced apart a distance S3, and the second signal line 160b and the third reference line 160e are spaced apart a distance S4. The first, second, and third reference lines 160c, 160d, and 160e provide additional isolation and a reference, such as ground, to ensure that adjacent structures and peripheral components do not interfere with the electromagnetic waves conducted by first signal line 160a and second signal line 160b and propagating through structural material 162. In one example, the distances S1, S2, S3, and S4 are substantially the same distance. In one example, the distances 51, S2, S3, and S4 can be different distances.

The first signal line 160a has a bottom surface 172, second signal line 160b has a bottom surface 174, first reference line 160c has a bottom surface 176, second reference line 160d has a bottom surface 178, and third reference line 160e has a bottom surface 180, which are coplanar and situated a distance H1 from top surface 168 and a distance H2 from bottom surface 170. The height H is equal to the distance H1 plus the distance H2. In one example, DCPW 160 is a symmetric DCPW, where the distance H1 is about equal to the distance H2 to center first signal line 160a, second signal line 160b, first reference line 160c, second reference line 160d, and third reference line 160e in structural material 162. In one example, DCPW 160 is an asymmetric DCPW, where the distance H1 is about ⅓ of the height H and the distance H2 is about ⅔ of the height H. In one example, DCPW 160 is an asymmetric DCPW, where the distance H1 is about ⅔ of the height H and the distance H2 is about ⅓ of the height H. In one example, DCPW 160 is an asymmetric DCPW, where the distance H1 is different than the distance H2.

In one example of a PCB, structural material 162 is a homogeneous material including a core dielectric material, glass-weave material, and prepreg material, where the core dielectric material is situated between the bottom surfaces 172, 174, 176, 178, and 180 and bottom surface 170, and the glass-weave material is situated between the bottom surfaces 172, 174, 176, 178, and 180 and top surface 168.

In operation, a measurement device, such as measurement device 28, is electrically coupled to each end of first signal line 160a and to each end of second signal line 160b, and first reference line 160c, second reference line 160d, and third reference line 160e are electrically coupled to a reference, such as ground. In one example, first reference line 160c, second reference line 160d, and third reference line 160e are electrically coupled to ground, which puts DCPW 160 in a ground-signal-ground-signal-ground (GSGSG) configuration to provide additional noise immunity, including common mode noise immunity.

The measurement device transmits and receives a differential signal through the first and second signal lines 160a and 160b to measure the phase delay per unit length of DCPW 160 and the insertion loss per unit length of DCPW 160. The DCPW 160 rejects common mode noise and improves the signal by about 3 dB. The measurement device provides the measured phase delay and insertion loss of DCPW 160 to a computing device, such as computing device 26. In one example, first reference line 160c, second reference line 160d, and third reference line 160e are electrically coupled to a reference, such as ground, while taking the measurements. In one example, top reference plane 164 and bottom reference plane 166 are electrically coupled to a reference, such as ground, while taking the measurements. In one example, top reference plane 164 and bottom reference plane 166 are electrically coupled to a different reference voltage, other than ground, while taking the measurements. In one example, the measurement device simultaneously measures the phase delay per unit length of DCPW 160 and the insertion loss per unit length of DCPW 160.

In one example, the measurement device is a VNA that sweeps a narrow frequency band across a broad range of frequencies to provide broadband measurements of the phase delay and insertion loss of DCPW 160. Sweeping a narrow frequency band across a broad range of frequencies suppresses noise that is out of the narrow frequency band, such that the VNA can provide a dynamic range on the order of 130 dB. In one example, the VNA provides a 1 mW signal having a 0 degree phase angle to first signal line 160a and a 1 mW signal having a 180 degree phase angle to second signal line 160b. In one example, the VNA provides a 5 dBmW signal having a 0 degree phase angle to first signal line 160a and a 5 dBmW signal having a 180 degree phase angle to second signal line 160b.

In one example, the measurement device is a TDR device that provides time domain broadband measurements of the phase delay and insertion loss of DCPW 160. Next, Fourier transforms or fast Fourier transforms (FFTs) are used to provide the phase delay and insertion loss of DCPW 160 over frequency. The TDR device is a broadband device that can provide a dynamic range on the order of 40 dB to 80 dB. In one example, the TDR device provides a +1 volt signal to first signal line 160a and a −1 volt signal to second signal line 160b.

The computing device receives the measured phase delay and insertion loss of DCPW 160 and compares the measured phase delay to a phase delay LUT, such as phase delay LUT 42, to obtain the relative permittivity ∈ᵣ of planar structure 60. Next, the computing device selects an insertion loss LUT, such as insertion loss LUT 44, corresponding to the relative permittivity ∈ᵣ of planar structure 60. The computing device compares the measured insertion loss to the selected insertion loss LUT to obtain the tangential loss tan δ of planar structure 60. Using the relative permittivity ∈ᵣ and tangential loss tan δ of planar structure 60, the material quality of planar structure 60 can be determined.

It will be appreciated that the above waveguides are illustrative of waveguides that can be measured using the techniques of the present application and that many other waveguides can be employed without departing from the techniques of the present application. Also, it will be appreciated that other structures, such as dielectrics, metallic, and semiconductive structures, and components, such as resistors, capacitors, inductors, voltage regulators, and processing units, can be situated above and/or below the reference planes as in multilayer structures.

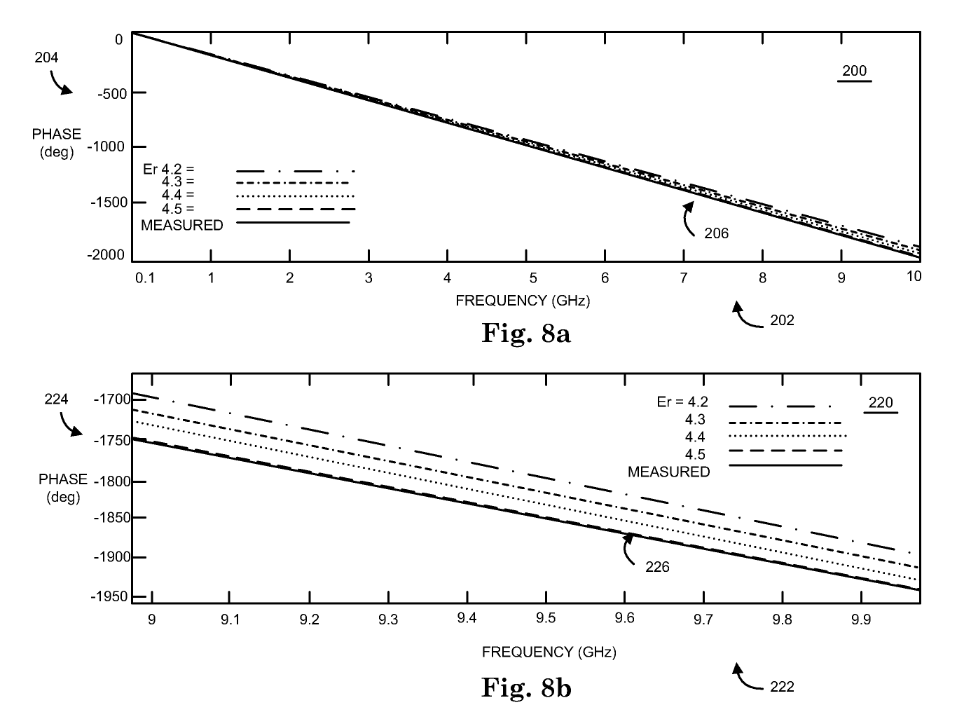

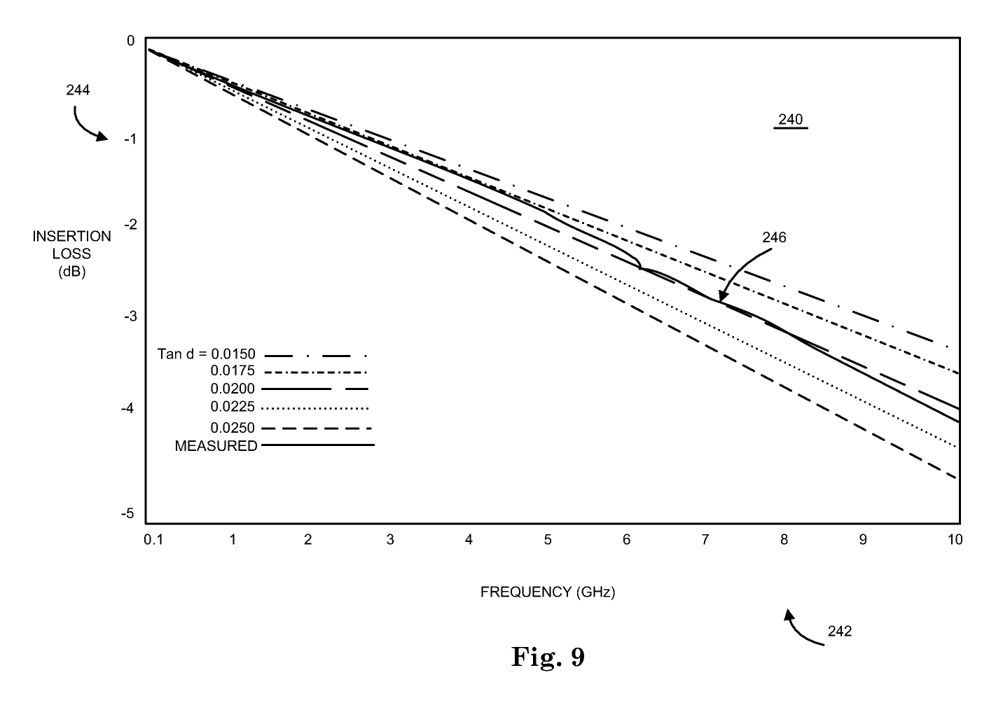

FIGS. 8A and 8B are graphs illustrating one example of a measured phase delay compared to a phase delay LUT and FIG. 9 is a graph illustrating one example of a measured insertion loss compared to an insertion loss LUT. A computing device, such as computing device 26 (shown in FIG. 1), receives the measured phase delay and the measured insertion loss of a planar structure, such as planar structure 22, from a measurement device, such as measurement device 28. The computing device compares points of the measured phase delay to points in the phase delay LUT to obtain the relative permittivity ∈ᵣ of the planar structure, such as planar structure 22. Next, the computing device selects an insertion loss LUT corresponding to the relative permittivity ∈ᵣ of the planar structure. The computing device compares points of the measured insertion loss to points in the selected insertion loss LUT to obtain the tangential loss tan δ of the planar structure. Using the relative permittivity ∈ᵣ and tangential loss tan δ of the planar structure, the quality of the planar structure can be determined and the planar structure can be passed or rejected.

In one example, the computing device uses a search algorithm, such as search algorithm 46, to compare the measured phase delay to the phase delay LUT and/or to compare the measured insertion loss to the insertion loss LUT. In one example, the computing device uses a recursive search algorithm to compare the measured phase delay to the phase delay LUT and/or to compare the measured insertion loss to the insertion loss LUT. In one example, the computing device uses a sequential search algorithm to compare the measured phase delay to the phase delay LUT and/or to compare the measured insertion loss to the insertion loss LUT. In one example, the computing device uses a hash search algorithm to compare the measured phase delay to the phase delay LUT and/or to compare the measured insertion loss to the insertion loss LUT. In one example, the computing device uses a binary search algorithm to compare the measured phase delay to the phase delay LUT and/or to compare the measured insertion loss to the insertion loss LUT. In one example, the computing device uses minimum mean square error in the comparison of points.

FIG. 8A is a graph 200 illustrating one example of the measured phase delay compared to a phase delay LUT over frequency from less than 1 GHz to 10 GHz. Frequency in GHz is plotted along the x-axis at 202 and phase delay in degrees is plotted along the y-axis at 204. The phase delays that correspond to each of the indexed relative permittivity ∈ᵣ values of 4.2, 4.3, 4.4, and 4.5 are plotted in graph 200. The measured phase delay of a fabricated waveguide is plotted in the black solid line 206. In one example, the measured phase delay was obtained using a VNA. In one example, the measured phase delay was obtained using a TDR device and Fourier transforms or FFTs.

FIG. 8B is a graph 220 illustrating one example of the measured phase delay compared to the phase delay LUT over frequency, zoomed into the 9 GHz to 10 GHz frequency range of graph 200. Frequency in GHz is plotted along the x-axis at 222 and phase delay in degrees is plotted along the y-axis at 224. The phase delays that correspond to each of the indexed relative permittivity ∈ᵣ values of 4.2, 4.3, 4.4, and 4.5 are plotted in graph 220. The measured phase delay of the fabricated waveguide is plotted in the black solid line 226.

The computing device compares points of the measured phase delay 226 to points in the phase delays that correspond to each of the indexed relative permittivity ∈ᵣ values of 4.2, 4.3, 4.4, and 4.5 to obtain the relative permittivity ∈ᵣ of the planar structure. In graph 220, the measured phase delay 226 corresponds to a relative permittivity ∈ᵣ of about 4.5 at each frequency from 9 GHz to 10 GHz.

In one example, the computing device interpolates between points in the phase delay LUT values to obtain an interpolated value of the relative permittivity ∈ᵣ. This interpolated value is used as the relative permittivity ∈ᵣ for indicating the quality of the planar structure. In graph 220, the interpolated value of the relative permittivity ∈ᵣ is about 4.52. This interpolated value of the relative permittivity ∈ᵣ is indexed to the indexed relative permittivity ∈ᵣ value of 4.5, which has a corresponding insertion loss LUT that is selected to obtain the tangential loss tan δ of the planar structure.

FIG. 9 is a graph 240 illustrating one example of the measured insertion loss compared to a selected insertion loss LUT over frequency from less than 1 GHz to 10 GHz. Frequency in GHz is plotted along the x-axis at 242 and insertion loss in dB is plotted along the y-axis at 244. The insertion losses that correspond to each of the indexed tangential loss tan δ values of 0.0150, 0.0175, 0.02000, 0.0225, and 0.0250 are plotted in graph 240. The measured insertion loss of the fabricated waveguide is plotted in the black solid line 246.

The computing device compares points of the measured insertion loss 246 to points in the insertion losses that correspond to each of the indexed tangential loss tan δ values of 0.0150, 0.0175, 0.02000, 0.0225, and 0.0250 to obtain the tangential loss tan δ of the planar structure. In graph 240, the measured insertion loss 246 corresponds to a tangential loss tan δ of about 0.0200.

In one example, the computing device interpolates between points in the selected insertion loss LUT to obtain an interpolated value of the tangential loss tan δ of the planar structure. In graph 240, the interpolated value of the tangential loss tan δ is about 0.021 at 10 GHz. This interpolated value of the tangential loss tan δ is used for indicating the quality of the planar structure.

In operation, the computing device receives the measured phase delay and the measured insertion loss of a planar structure from a measurement device over a broadband frequency range, such as from 100 megahertz (MHz) to 10 GHz. The computing device begins at an initial present frequency, such as 100 MHz, and compares the measured phase delay at the present frequency to the phase delay LUT at the present frequency to obtain the relative permittivity ∈ᵣ of the planar structure at the present frequency. Next, the computing device selects an insertion loss LUT corresponding to the relative permittivity ∈ᵣ of the planar structure at the present frequency and compares the measured insertion loss at the present frequency to the selected insertion loss LUT at the present frequency to obtain the tangential loss tan δ of the planar structure at the present frequency.

The computing device compares the present frequency to a predefined end frequency, such as 10 GHz, and if the present frequency does not match the end frequency, the computing device increments to the next present frequency, such as in 100 MHz increments. Next, the computing device compares the measured phase delay at this present frequency to the phase delay LUT at this present frequency to obtain the relative permittivity ∈ᵣ of the planar structure at this present frequency. Next, the computing device selects an insertion loss LUT corresponding to the relative permittivity ∈ᵣ of the planar structure at this present frequency and compares the measured insertion loss at this present frequency to the selected insertion loss LUT at this present frequency to obtain the tangential loss tan δ of the planar structure at this present frequency.

The computing device compares the present frequency to the end frequency and repeats the process if the present frequency does not match the end frequency. If the present frequency matches the end frequency, the process ends. In one example, the end frequency can extend well beyond 100 GHz and is valid up to the atomic resonance of the metallic waveguide.

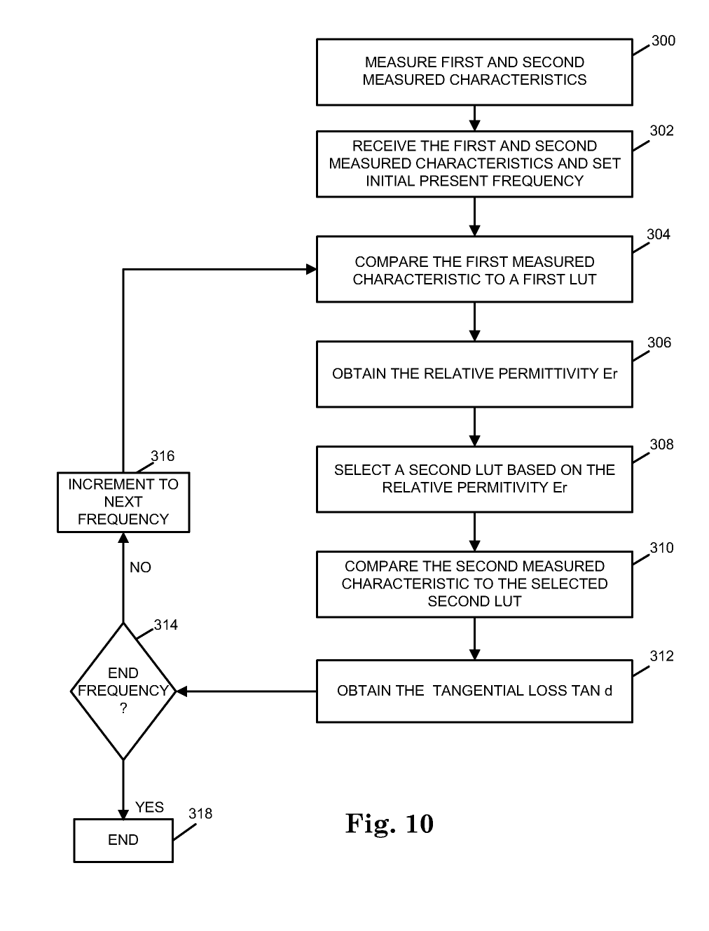

FIG. 10 is a flow chart diagram illustrating one example of the process of obtaining the relative permittivity ∈ᵣ and tangential loss tan δ of a planar structure over a broadband frequency range, such as from 100 MHz to 10 GHz. At block 300, a measurement device, such as measurement device 28, measures a first measured characteristic, such as the phase delay per unit length, and a second measured characteristic, such as the insertion loss per unit length, of a waveguide, such as waveguide 24, over the broadband frequency range. The measurement device provides the first and second measured characteristics to a computing device, such as computing device 26. In one example, the measurement device simultaneously measures the phase delay per unit length and the insertion loss per unit length of the waveguide.

At block 302, the computing device receives the first and second measured characteristics and sets an initial present frequency value, such as 100 MHz. At block 304, the computing device compares the first measured characteristic, such as the measured phase delay, to a first LUT, such as a phase delay LUT, at the present frequency. At block 306, the computing device obtains the relative permittivity ∈ᵣ of the planar structure from the first LUT at the present frequency. Next, at block 308, the computing device selects a second LUT, such as an insertion loss LUT, corresponding to the relative permittivity ∈ᵣ of the planar structure at the present frequency.

At block 310, the computing device compares the second measured characteristic, such as the measured insertion loss, to the selected second LUT, at the present frequency. At block 312, the computing device obtains the tangential loss tan δ of the planar structure at the present frequency from the second LUT. In one example, the tangential loss tan δ of the planar structure at three different frequencies is different, such as 0.0175 at 1 GHz, 0.019 at 5 GHz, and 0.021 at 10 GHz.

At block 314, the computing device compares the present frequency to an end frequency, such as 10 GHz. If the present frequency does not match the end frequency, the computing device increments the present frequency to the next present frequency at block 316, such as in 100 MHz increments, and repeats the process from block 304 to block 314. If the present frequency matches the end frequency at block 314, the process ends at block 318. Using the relative permittivity ∈ᵣ and tangential loss tan δ of the planar structure over the broadband frequency range, the quality of the planar structure can be ascertained and the fabricated planar structure can be passed or rejected.

In the present detailed description, reference was made to the accompanying drawings which form a part hereof, and in which was shown by way of illustration specific embodiments in which the techniques of the present application may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the techniques of the present application. It is to be understood that features of the various embodiments described herein may be combined with each other, unless specifically noted otherwise.

Although specific embodiments have been illustrated and described herein, it will be appreciated that a variety of alternate and/or equivalent implementations may be substituted for the specific embodiments shown and described without departing from the scope of the techniques of the present application. This application is intended to cover any adaptations or variations of the specific embodiments discussed herein.

1. A system comprising:
a computing device to compare a first measured characteristic of a planar structure to a first look up table and obtain relative permittivity of the planar structure based on the comparison of the first measured characteristic, and to compare a second measured characteristic of the planar structure to a second look up table and obtain tangential loss of the planar structure based on the comparison of the second measured characteristic.

2. The system of claim 1, wherein the relative permittivity of the planar structure for use to select the second look up table to obtain the tangential loss of the planar structure.

3. The system of claim 1, wherein the computing device to compare the first measured characteristic to points in the first look up table and interpolate between the points in the first look up table to obtain the relative permittivity of the planar structure.

4. The system of claim 1, wherein the computing device to compare the second measured characteristic to points in the second look up table and interpolate between the points in the second look up table to obtain the insertion loss of the planar structure.

5. The system of claim 1, wherein the first measured characteristic includes phase delay per unit length of a waveguide in the planar structure and the second measured characteristic includes insertion loss per unit length of the waveguide in the planar structure.

6. The system of claim 1, further comprising a measurement device to simultaneously measure the first measured characteristic and the second measured characteristic.

7. The system of claim 1, further comprising a measurement device to measure the first measured characteristic and the second measured characteristic, wherein the measurement device includes a vector network analyzer to sweep narrow frequency bands to provide a broadband measurement of the first measured characteristic and the second measured characteristic.

8. The system of claim 1, further comprising a measurement device to measure the first measured characteristic and the second measured characteristic, wherein the measurement device includes a time domain reflectometry device to obtain broadband measurements of the first measured characteristic and the second measured characteristic.

9. The system of claim 1, wherein the computing device to compare the first measured characteristic of the planar structure at a present frequency to the first look up table at the present frequency to obtain the relative permittivity of the planar structure at the present frequency and compare the second measured characteristic of the planar structure at the present frequency to the second look up table at the present frequency to obtain the tangential loss of the planar structure at the present frequency and then the computing device to change the present frequency to a next present frequency and repeat the comparisons at the next present frequency.

10. A system comprising:
a measurement device to measure phase delay per unit length of at least one waveguide in a planar structure and insertion loss per unit length of the at least one waveguide in the planar structure; and
a computing device to compare the phase delay per unit length to a phase delay look up table and obtain relative permittivity of the planar structure based on the comparison of the phase delay per unit length, and to compare the insertion loss per unit length to an insertion loss look up table and obtain tangential loss of the planar structure based on the comparison of the insertion loss per unit length.

11. The system of claim 10, wherein the relative permittivity of the planar structure for use to select the insertion loss look up table to obtain the tangential loss of the planar structure.

12. The system of claim 10, wherein the at least one waveguide includes one of a stripline, a differential stripline, a coplanar wave guide, and a differential coplanar wave guide.

13. The system of claim 10, wherein the measurement device to obtain broadband measurements of the phase delay per unit length of the at least one waveguide in the planar structure and the insertion loss per unit length of the at least one waveguide in the planar structure.

14. The system of claim 10, wherein the phase delay look up table and the insertion loss look up table are provided via one of a three dimensional field solver and resonant cavity structures.

15. A method comprising:
comparing a first measured characteristic of a planar structure to a first look up table via a computing device;
obtaining relative permittivity of the planar structure from the first look up table based on the comparison of the first measured characteristic;
comparing a second measured characteristic of the planar structure to a second look up table via the computing device; and
obtaining tangential loss of the planar structure from the second look up table based on the comparison of the second measured characteristic.

16. The method of claim 15, further comprising:
selecting the second look up table to obtain the tangential loss of the planar structure using the obtained relative permittivity of the planar structure.

17. The method of claim 15, further comprising:
interpolating between points in the first look up table to obtain the relative permittivity of the planar structure.

18. The method of claim 15, further comprising:
interpolating between points in the second look up table to obtain the insertion loss of the planar structure.

19. The method of claim 15, further comprising:
measuring phase delay per unit length of a waveguide in the planar structure as the first measured characteristic; and
measuring insertion loss per unit length of the waveguide in the planar structure as the second measured characteristic.

20. The method of claim 15, further comprising:
measuring the first measured characteristic and the second measured characteristic using one of a vector network analyzer that sweeps narrow frequency bands to provide a broadband measurement of the first measured characteristic and the second measured characteristic and using a time domain reflectometry device to obtain broadband measurements of the first measured characteristic and the second measured characteristic.
